(19) United States
(12) Patent Application Publication
(10) Pub. No.: US 2023/0185064 A1
(43) Pub. Date: Jun. 15, 2023

(54) Compact Bi-Telecentric Projection Devices

(71) Applicant: Fathom Radiant, PBC, Boulder, CO (US)

(72) Inventors: Kaia Williams, Denver, CO (US); Benjamin Braker, Louisville, CO (US); Omer Tzang, Louisville, CO (US); Robert T. Weverka, Boulder, CO (US); Keith Behrman, Boulder, CO (US)

(21) Appl. No.: 18/076,299

(22) Filed: Dec. 6, 2022

Related U.S. Application Data
(60) Provisional application No. 63/286,450, filed on Dec. 6, 2021.

(51) Int. Cl. G02B 13/22; G02B 5/18; H01S 5/42; H01S 5/40; H04B 10/50; G02B 15/14

(52) U.S. Cl. CPC G02B 13/22; G02B 5/1876; H01S 5/423; H01S 5/4012; H04B 10/506; G02B 15/1421

(57) ABSTRACT

A compact bi-telecentric device includes refractive lenses and takes in light from a grid of emitters at the object plane and images them to a grid of receivers. It provides the capacity to combine multiple wavelengths of emitters at the object plane into a single receiver. The device is quite compact, less than 25 mm in length from object to image, and having a maximum diameter for any element of less than 4 mm. The device includes four optical lens elements, three of which have a positive focal length and one of which has a negative focal length. The device includes at least one diffractive optical element. The lens elements are separated into two distinct groups which each have positive optical power, separated by an aperture stop which may or may not be enabled by a physical surface. A diffractive element enables wavelength division multiplexing and compensates for distortion from the bi-telecentric device.

### BACKGROUND OF THE INVENTION

### Field of the Invention

The present invention relates to bi-telecentric optics. In particular, the present invention relates to compact bi-telecentric projection/imaging devices including refractive lenses and diffractive optics.

### Discussion of Related Art

Currently, bi-telecentric optics are often used in machine vision. Such systems often include optical elements of various optical materials to improve color accuracy. They usually allow varying distances between the object and the first optical element, since it is difficult to place the object precisely relative to the system. Moderate amounts of distortion are acceptable.

### SUMMARY OF THE INVENTION

It is an object of the present invention to provide improved bi-telecentric optics, such as bi-telecentric projection/imaging devices. One useful application is for transmitting data from, for example, a large array of optical fibers (e.g 2000) to a separate large array of optical devices (and back if desired). In such applications, an extremely low amount of distortion (for example under 0.05%) is desirable, since the location of the fibers is difficult to adjust. All of the optical elements may be formed of the same material (e.g. plastic) when color accuracy is not vital. The optical elements, especially on the image side of the device have high numerical apertures to match the numerical apertures of the fibers. The object sources may comprise VCSEL lasers.

Some features of such a lens include placing an optical element extremely close to the object, and disposing all of the optical elements within a small area, for example within 25 mm in length, with no element having a diameter of more than 4 mm. In one example, the device includes a first lens group having a refractive lens of positive focal length and another of negative focal length, where the first lens group has positive power. A second lens group has two refractive lenses, both positive focal length so the second lens group also has positive power. The two groups are separated by an aperture stop which may or may not be a physical surface.

The small footprint of the device allows for very low vibration. It also saves space and materials.

### EXAMPLES

Bi-telecentric finite-conjugate imaging system with extremely low distortion (<0.05%) and sub-diffraction limited wavefront performance.
An imaging system designed to work with relatively large numerical apertures at the object (NA>0.04) and at the image (NA>0.15).
Specific design form that accomplishes specifications with a low number of elements (4) and a notably small package size (4×4×25 mm)
The system can be used in both directions, equally transmitting either an enlarged image or a reduced image with identical magnification factors.

Some embodiments include a diffractive element such that the bi-telecentric system may be used for multiplexing and demultiplexing signals, such as from an array of pixel lasers in the object plane to an array of optical fibers in the image plane. The diffractive element may be customized to adjust for distortions within the bi-telecentric device, for example to project signals from an input array to uniform array or grid of detectors or optical fibers.

A wavelength division multiplexing (WDM) system includes a source array for providing input beams, a first lens group and a second lens group configured to create an imaging configuration, and a diffractive element. The first lens group has two positive focal length lenses configured to collimate beams. The second lens group has a negative focal length lens configured to bring the collimated beams to a weak focus, and a positive focal length lens configured to reduce the curvature of the field in the output plane.

An output array of locations is disposed on the opposite side of the imaging configuration from the source array. A diffractive element is oriented between the first lens group and the second lens group at an imaging configuration Fourier plane. The diffractive element is configured to enable specific input beams to map to selected output array locations based on the wavelengths of the input beams. The diffractive element might be, for example a blazed grating, a hologram, or a binary phase modulator.

The WDM system operates in a reverse direction such that beams from the output array of locations are mapped to specific locations in the source array.

The source array may include VCSELs to generate the input beams, or it may include an array of optical fibers, which deliver the input beams. The output array may include optical fibers or detectors.

The system is designed to be very small, for example under 10 mm track length. The entire imaging configuration only requires two lenses in the first lens group and two lenses in the second lens group.

The lenses might be Fresnel lenses or meta lenses. The system may have an absolute magnification between 1.5 and 6.

A wavelength division multiplexing system includes two lens elements disposed in an imaging configuration, a diffractive element disposed between the two lens elements, an array of light sources, and an array of receivers (for example 8 receivers). Individual beams from the array of light sources are directed to specific receivers by the two lens elements and the diffractive element based on beam wavelengths. The diffractive element is configured to compensate for distortion caused by the two lens elements. The receivers might comprise detectors or optical fibers. The light sources may comprise VCSELs or an array of optical fibers. The system also operates in the reverse direction by including transmitters in the receiver array and providing receiving optical fibers at the source array.

The method of accomplishing WDM includes the steps of in a bi-telecentric lens system having a first lens set and a second lens set, disposing a diffractive element between the first lens set and the second lens set, configuring the lens system and the diffractive element to accomplish WDM of beams from an array of light sources to an array of image locations, and compensating for distortion caused by the lens system. The compensating step might include measuring or calculating distortion caused by the lens system and configuring the diffractive element based on the measured distortion. It might include adjusting spacing of lenses or configuring the diffraction element based on measured distortion. Distortion might be calculated and then also measured once the system in configured. Then further adjustments would be made as above.

Fabrication might be accomplished by fabricating multiple sets of each element on a single substrate (e.g. multiples of a first lens from the first lens set on one substrate, multiples of another lens from the first lens set on a second substrate, multiple diffractions elements on a third substrate, etc.) This allows the substrates to be adjusted relative to each other based on distortion and other factors. Then the substrates are separated such that one of each element is configured together to form the WDM combinations. For example, the combinations might be separated with a dicing saw.

Detectors might be located according to distortion caused be the lens system so the detectors are in the right place even if the distortion isn't removed. The system may operate in the opposite direction by, for example, interleaving VCSELs with detectors at the image locations.

### BRIEF DESCRIPTION OF THE DRAWINGS

FIG. 1 is a schematic block diagram of a bi-telecentric projection device.

FIG. 2 is a schematic block diagram of the bi-telecentric projection device of FIG. 1 operated in reverse.

FIG. 3A is a block diagram illustrating the optical elements of an embodiment of the device of FIGS. 1 and 2. FIG. 3B is a first example of an image plane of the embodiment of FIG. 3A. FIG. 3C is a second example of an image plane of the embodiment of FIG. 3A.

FIG. 4 is a specific example of the bi-telecentric projection device of FIG. 3.

FIG. 5A is a block diagram of a second embodiment of the device of FIGS. 1 and 2, including a diffractive element. FIG. 5B is a first example of an image plane of the embodiment of FIG. 5A. FIG. 5C is a second example of an image plane of the embodiment of FIG. 5A.

FIG. 6 is a block diagram of a specific example of a bi-telecentric projection device wherein the system enables wavelength division multiplexing.

FIG. 7 is a block diagram showing how many bi-telecentric projection devices may be fabricated together.

FIG. 8 is a block diagram showing a bi-telecentric projection device integrated in a system alongside VCSELs, photodetectors, and optical fibers.

### DETAILED DESCRIPTION OF THE INVENTION

The device is an arrangement of refractive lenses that produce a magnified or de-magnified image of an input object. The object seen by the device is placed near (e.g. within one millimeter) of the first element, and the image produced by the device is formed after the final element. In a preferred embodiment, this image is formed within 10 millimeters of the final element.

The device takes in light from a grid of emitters, at the object plane or via optical fibers and images them to a grid of receivers or optical fibers. The device is intended to be quite compact, less than 25 mm in length from object to image, and having a maximum diameter for any element of less than 4 mm. The aperture stop may not be a physical surface; the angular extent of the bundle of rays formed by the system may instead be limited by the incoming beam of light. Moreover, the device is capable of receiving and emitting light from both directions, allowing it to both magnify the beams in one direction and de-magnify the beams in the second direction.

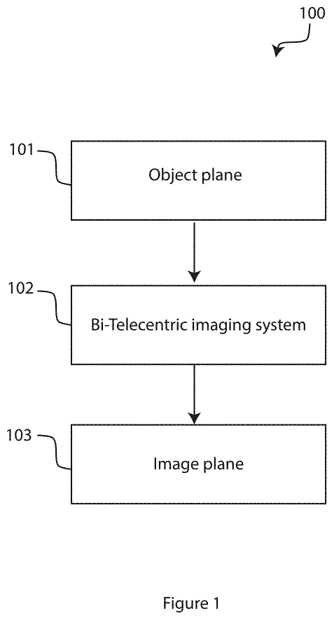

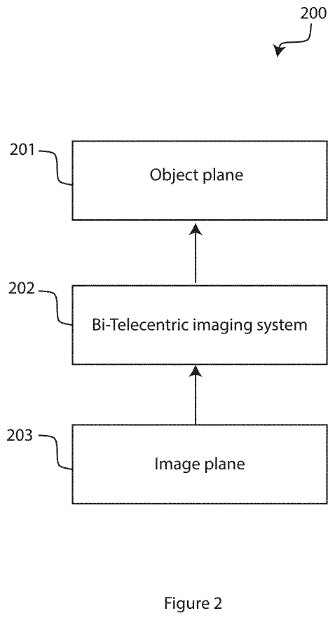

FIG. 1 is a top-level block diagram of the device 100. An object plane 101 is imaged by the bi-telecentric system 102 onto an image plane 103. FIG. 2 illustrates that the device works in reverse 200: the bi-telecentric system 202 images the image plane 203 onto the object plane 201. The terms “object plane” and “image plane” are thus used to differentiate the two planes for clarity, rather than indicating where an actual object and image exist.

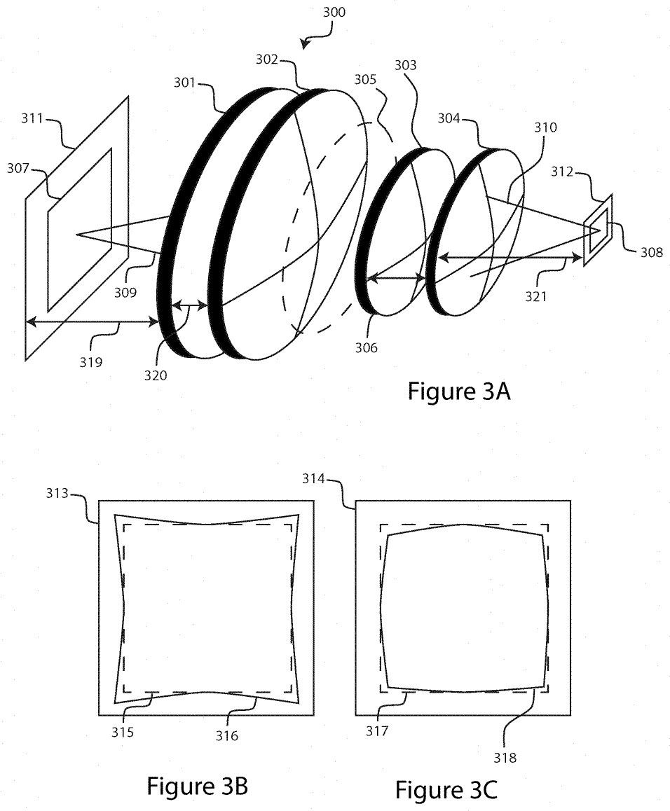

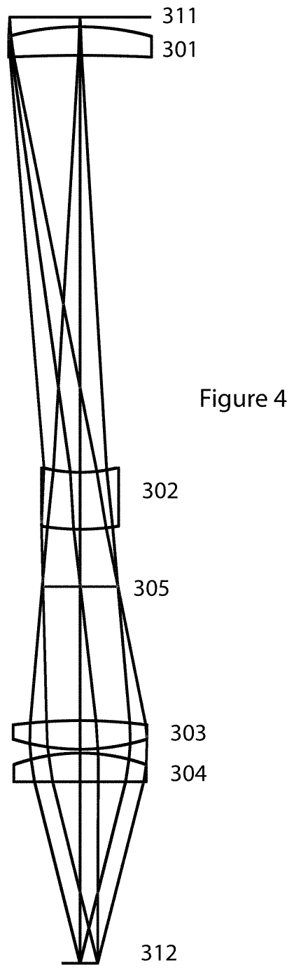

FIG. 3A is a more detailed block diagram of a bi-telecentric projection system 300. FIG. 4 is a block diagram illustrating a specific example 400 of a bi-telecentric projection device like 300. Device 300 includes four elements 301, 302, 303, and 304, three of which have a positive focal length and one of which has a negative focal length. The elements are separated into two distinct groups which each have positive optical power, separated by an aperture stop 305 which may or may not be enabled by a physical surface. The lens is therefore reminiscent of a standard Keplarian telescope operated at finite conjugates.

The first lens group consisting of elements 303 and 304 is designed so that it relays the image of object 312 to a weak (aberrated) focus. The elements 302 and 301 in the second lens group are configured to correct for the aberrations inherent in the action of elements 303 and 304; specifically, element 302 corrects for spherical aberration and coma; element 301 corrects for curvature of the field of view.

The first group (301 and 302) is composed of a positive focal length lens 301 and a negative 302 focal length lens which are spaced apart significantly; the positive element 301 primarily steers the off-axis beams towards the negative element 302 in a uniform fashion (thereby flattening the image plane when the system is used in reverse) while enabling the incoming beams to be telecentric. The negative lens 302 flattens the wavefront of the beams formed by the first element 301 significantly and may impart a significant volume of undercorrected third-order spherical aberration to balance the spherical aberration in the second group.

The second group is formed of two elements 303 and 304 with nearly identical focal lengths. The space 306 between the two elements elongates along the X and Y dimensions transverse to the optical (Z) axis, and can help to correct the third-order off-axis aberrations, particularly astigmatism. The on-axis aberrations may also be corrected with the help of a distribution of at least 5 weakly conic curvatures throughout the lens system.

The imaging properties of device 300, 400 which are particularly useful for our application are the combination of the magnification (the ratio of the object 307 size to the image 308 size), the numerical apertures of the input beam and the output beam (309 and 310), and the fields of view (311 and 312). The device produces an image 308 that is magnified by a factor of between 0.22 and 0.29. The image 308 formed by the device has a magnitude of optical distortion of less than 0.05%.

FIG. 3B illustrates optical distortion for a first image plane 313 where distortion causes the imaging system to produce a distorted image 316 which deviates from ideal image 315. FIG. 3C illustrates optical distortion for a second image plane 314 where distortion causes the imaging system to produce a distorted image 318 which deviates from ideal image 317. The numerical aperture of the input 309 (object-side) beam of light entering the lens is less than 0.06, and is therefore magnified to form an output beam of light 310 on the output (image-side) of the device with a numerical aperture of less than 0.24. The full field of view is less than 4 mm at the image plane 312, corresponding to less than 0.35 degrees at the aperture stop 305.

One additional detail which further improves this design for our application is the wavelength. The device is capable of transmitting beams of light from between 800 and 1000 nanometers in wavelength.

The device is designed to, for example, enable the coupling of a massive multicore fiber to an array of emitters and detectors on an optoelectronic substrate.

Those skilled in the art will appreciate that various embodiments fall within the spirit of this invention. One alternative embodiment of this device has a magnitude of optical distortion much greater than 0.05% and is compensated for by adjusting the relative spacing of the optical components on either the image plane or the object plane.

A second alternative embodiment of this device has magnification and fields of view are significantly different from the first embodiment, such that either
The magnification is identical to the first embodiment, i.e. 3.5≤m≤4.5, where m is the unitless absolute value of the ratio of the object size to the image size, but the field of view of the object plane and the image plane are significantly smaller than the enabling embodiment, i.e. the full field of view is less than 0.18 degrees at the aperture stop.
The field of view is identical to the first embodiment, such that the full field of view is less than 0.35 degrees at the aperture stop, but the magnification is significantly smaller than the enabling embodiment, i.e. 1.5≤m≤3.5, where m is the unitless absolute value of the ratio of the object size to the image size.

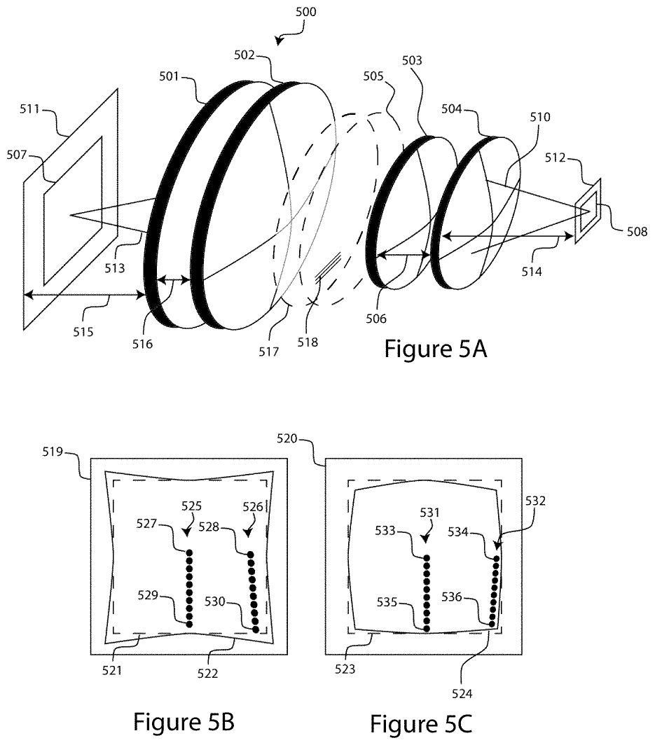

FIGS. 5A-7 illustrate the invention being used to create a wavelength division multiplexed (WDM) system. A WDM system as depicted here is used for a plurality of purposes. It may be used to separate and focus light of one source into a set of positions according to wavelength. In addition, it may combine and focus light from multiple positions and multiple wavelengths into a single output position and angle. And, it may be used for both purposes; light from one source may be separated and focused when traveling in one direction through the system whereas light traveling in the second direction through the system may be combined and focused onto a single output position and angle.

Said WDM system is useful for various reasons; in one application, a WDM system can be used to modulate a set of sources, each with a unique wavelength, and combine said sources into a single optical waveguide. Thus, many channels of information can be combined onto an optical waveguide. This function is referred to as wavelength multiplexing. In said application, a WDM system may also be used to separate the light from said waveguide structure into a plurality of spatial locations corresponding to unique wavelengths. This function is referred to as wavelength de-multiplexing.

This invention addresses various methods of multiplexing and de-multiplexing which may be accomplished within an imaging system. In communications systems, such multiplexing and de-multiplexing may be used to combine signals from multiple wavelength-separated lasers into an optical fiber core placed at the single optical waveguide, and it may be used to separate signals from the same optical fiber core across detectors placed at multiple locations.

FIG. 5A depicts one form of the multiplexing embodiment. In FIG. 5A, a wavelength division multiplexing (WDM) system (500) is based on a bi-telecentric lens system, such as that shown in FIGS. 1-4. In said WDM system, a first group of lenses (here 501, 502) are placed substantially along the optical axis of a second group of lenses (here 503, 504) such that there is an aperture stop (505) somewhere within the imaging system. When substantially aligned, the WDM system (500) forms the image (508) of the object (507) within the field of view of the object plane (511). When operating in this direction, the imaging system is configured to collect light within an object numerical aperture (513) and emit a substantial fraction of that light into an image numerical aperture (510).

In the particular embodiment illustrated in FIG. 5A, the image magnification is less than 1, such that the image size is less than the object size; and, conversely, the image numerical aperture is larger than the object numerical aperture. Said embodiment obeys the conservation of etendue which, in some embodiments, would enable a diverging VCSEL placed in the object plane (511) to be efficiently coupled into a fiber placed in the image plane (512). Such a WDM system may also be configured to work in the opposite direction such that it forms an image of objects placed within the field of view at plane 512. Under such a configuration, light emitted by an optical fiber in plane 512 may be coupled into a detector in plane 511.

WDM system (500) is modified further by placing a diffractive element (517) substantially close to the Fourier plane of the imaging system. In one embodiment, the diffractive element is a linear blazed grating wherein the rulings of the grating (518) are aligned substantially along the same dimension and the blaze is constructed to maximize the diffraction efficiency along one diffraction order (the +1 or −1, for example).

A source array of input beams (e.g. VCSELs or other emitters, or an array of optical fibers) is mapped to an output array of locations based on the wavelengths of the input beams and their location in the source array. Detectors, transceivers, or an array of optical fibers might be placed at the output array of locations. Of course the system also operates in the reverse direction, with beams from output array locations mapped to specific locations in the source array, and detectors or the like placed at those source array locations.

Images formed through the WDM system (500) are illustrated for two embodiments; FIG. 5B shows an imaging system with pincushion distortion (522) at image plane 519, and FIG. 5C shows an imaging system with barrel distortion (524) at image plane 520. Ideal images are 521 and 523. A third embodiment would be a system with no distortion. Under these distortion conditions, when an object is imaged from object plane (511) to image plane (512), one can describe the effects of the diffractive element (517) as follows.

In the pincushion distortion case (522), the diffractive element may cause an image of an unresolvable point to be separated into many images according to the spectral content. For object locations within a plane defined by the optical axis and the normal to the grating rulings, the diffraction in the image plane may be co-planar such that short wavelengths are imaged at one position 527 which is less deviated from the desired image location 525 than longer wavelengths position 529 from their desired position 526. For objects along this plane, WDM system 500 provides a method to precisely divide wavelengths from one object onto precise locations along the image plane.

In one embodiment, an optical fiber core is placed in the object plane 511 and light from said fiber core may be imaged onto a set of detectors in the image plane (512). In said embodiment, the detector locations may be chosen to be centered on the image spots of specific wavelengths. This effect may also affect the spots in the barrel distortion embodiment of FIG. 5C (533 to 535). Short wavelength image positions 533 are closer to desired image location 531 than long wavelength image positions 534 are from their desired location 532.

Distortion of the imaging system may cause the locations of the diffracted wavelengths to shift substantially. When an imaging system is significantly distorted, the locations shift enough to degrade the coupling between a grid of sources placed in the object plane 507 and a de-magnified grid of detectors placed in the image plane 508. In applications where the sources are VCSELs and the detectors are single mode optical fiber cores, even 0.2 um deviations from a perfect image of a grid would be deemed as significantly distorted; said deviations degrade the coupling between the VCSEL and the optical fiber core.

When the imaging system exhibits distortion, an image 530 of a long wavelength object will experience both diffraction and distortion relative to image 528 of the short wavelength object, causing the resulting positions of intermediate wavelengths to lie along a curved path. For an image (522) formed under pincushion distortion, the locations of wavelengths diffracted at the center of the field of view (527 to 529) will not fall on the same grid as wavelengths diffracted from the edge of the field of view (528 to 530).

Several embodiments of the systems of this invention combine the distortion and the grating diffraction to deliver a wavelength division multiplexing system. One system solution may place the photodetector locations at the precise, well behaved positions (527, 529, 528, 530) which correspond to the center of the wavelengths in the presence of distortion and diffraction. In another embodiment, one may adjust one lens spacing (516) relative to a second lens spacing (506). In said embodiment, the lens may be built with adjustable collars to enable such wavelength tuning. In one variation of said embodiment, layers of glass may be inserted between the lenses to shift their optical path length. And in yet another variation, the lenses may be deformed to shift their focal lengths. In yet another variation of said embodiment, the lens positions (514 and 515) may be further adjusted to substantially improve the focus of the system.

In another embodiment, the lenses need not be changed and instead the grating is customized. In said design, the lens distortion may be measured or calculated and the grating may be optimized to minimize the resulting distortion. In said embodiment, the grating may be considered to be a diffractive optic rather than a grating; as such, the surface will deviate from one consisting of grating rulings (518) to instead be composed of a two dimensional surface of varying thickness. In one extension of this embodiment, the two dimensional surface may be a diffractive optical element constructed of discrete regions, each having discrete heights. In one version of said extension, the height at each region of the diffractive optical element may be designed using an iterative optimization method such as the Gerchberg-Saxton algorithm to converge on an arrangement of heights which sufficiently compensate for the distortion in the lens. Compensating for the distortion allows wavelength division multiplexing on a substantially rectangular grid in the image plane.

In one embodiment of the invention, a WDM system (500) may be constructed when the distortion is significant, and it may separate a set of wavelengths from one or more optical fiber cores to fall onto a set of detectors. In one variation of said embodiment, one or more optical fiber cores may be placed in one or more rows at the object plane (512) and detectors may be placed in the image plane (511). In said variation, the diffraction of a linear grating (517) and the distorted imaging system focuses spots to distorted and diffracted positions (528, 530, 534, 536). Under such conditions, a set of individual detectors may be positioned substantially aligned to the distorted and diffracted positions (528, 530, 534, 536), In this manner, a set of wavelengths emitted by the one or more optical fibers will impinge onto the set of detectors.

In another embodiment of the invention, a WDM system (500) may be constructed when the distortion is significant, and it may collect light at one or more wavelengths from a set of one or more lasers and couple said light into a single optical fiber core within a set of optical fiber cores. In one variation of said embodiment, one or more lasers may be placed in the object plane (511) and a row of optical fiber cores may be placed in the image plane (512). In said variation, the diffraction of a linear grating (517) and the distorted imaging system diffracts light from distorted and diffracted positions (528, 530, 534, 536) in the object plane such that it couples into optical fiber cores. Under such conditions, a set of individual VCSELs may be positioned substantially aligned to the distorted and diffracted positions (528, 530, 534, 536), In this manner, a set of wavelengths emitted by the one or more lasers may couple into a single optical fiber core. In one variation of said embodiment, the diffracted positions (528, 530, 534, 536) may be predicted in a simulation, and the VCSEL positions may be designed and fabricated to match said diffracted positions. In a second variation of said embodiment, the diffracted positions (528, 530, 534, 536) may be measured for one or more WDM systems, and the VCSEL positions may be designed and fabricated to match said diffracted positions. In an alternative variation, the VCSELs may be iteratively chosen during fabrication to match the diffracted positions.

In one embodiment of the invention, a WDM system (500) is constructed with lasers and detectors substantially in the same plane with light coupling in and out of fiber cores at the opposite end of the WDM system.

In one embodiment of the invention, a WDM system (500) may be constructed such that the distortion of the lenses (501, 502, 503, 504) may be substantially compensated using a diffractive element 517. In said embodiment, we construct a design such that lenses 501 and 502 place the Fourier plane of object plane 511 at the diffractive element 517, and lenses 503 and 504 place the Fourier plane of the diffractive element 517 at image plane 512. Under such conditions, each angle of light at the diffractive element to and from lenses 501 and 502 corresponds to positions in object plane 511. Likewise, each angle of light at the diffractive element to and from lenses 503 and 504 corresponds to a position at object plane 511. Under conditions where the imaging system exhibits distortion in the resulting position, said distorted positions may be mapped to distorted angles at the diffractive element 517.

Using this relationship, we identify distorted input angles which are mapped to distorted output angles, and this mapping can be done using a diffractive element. In one variation of this embodiment, a diffractive element may be designed with gratings to effectively couple each input angle to an output angle with a tilted offset. In said variation, the diffraction at this tilted offset may compensate for the linear component of the distortion such that the resulting beams fall onto a linear grid in the image plane. When said offset is applied to each input angle, the resulting set of focused spots may be formed substantially onto a rectangular grid. Thus, a WDM system may be constructed such that the diffraction substantially compensates for the lenses.

In some embodiments, a bi-telecentric projection system may be implemented using lenses with substantially small sag. By sag, we mean the distance between the vertex point along the curve of the lens and the plane drawn through at least three edges of the lens curve. When lenses are formed above or below a planar substrate, the sag is the distance from the vertex along the curve of the lens to the surface of the substrate.

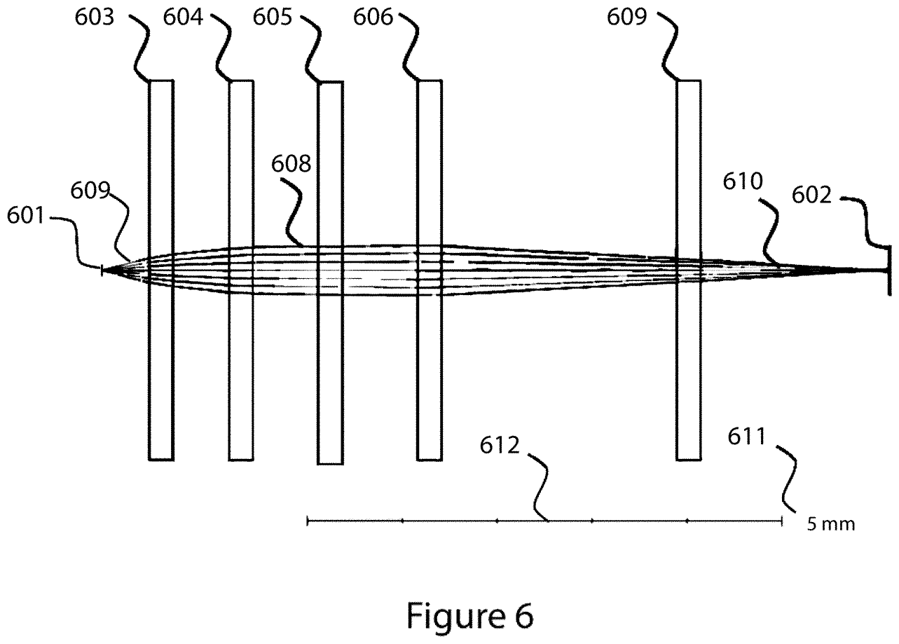

One example of this embodiment is illustrated in FIG. 6, wherein a bi-telecentric imaging configuration is established between two planes (601 and 602). In said embodiment, four lenses (603, 604, 606, and 607) create a bi-telecentric imaging configuration wherein a Fourier plane is created at element 605 such that element 605 may be a diffractive element. Such an approach here is shown to be very compact, with scale 612 indicating a total size of 5 mm (611). This compact nature is useful when reducing the footprint of the lens system. In said embodiment, the presence of a diffractive element may create the conditions necessary for WDM functionality. In one variation of said embodiment, one or more optical fiber cores may be placed at plane 601 and one or more VCSELs collimated by one or more microlenses may be placed at plane 602.

In the variation of the embodiment illustrated in FIG. 6, the bi-telecentric condition has a magnification greater than 1 such that the image of plane 601 is magnified at plane 602. In said variation, the numerical aperture of the fiber (609) is illustrated as being larger than the numerical aperture of the collimated VCSEL (610). In one variation of said embodiment, the four lenses may be implemented as Fresnel lenses. This embodiment may have a system track length of under 10 mm. In some embodiments, the absolute value of the magnification is greater than 1.5 and less than 6 when operated in a magnifying direction. In other variations, the four lenses may be implemented as refractive lenses or meta lenses. We refer to metalenses as a surface in which the phase is induced via the response of nanostructures (called nanoantennas) built on the surface of the substrate material. In yet other variations, one or more lenses may be implemented as a Fresnel lens whereas one or more of the remaining lenses may be implemented as a refractive lens. In one variation of said embodiment, at least one of the four lenses may have lens structures on both sides. In one embodiment, there may be more than four lenses.

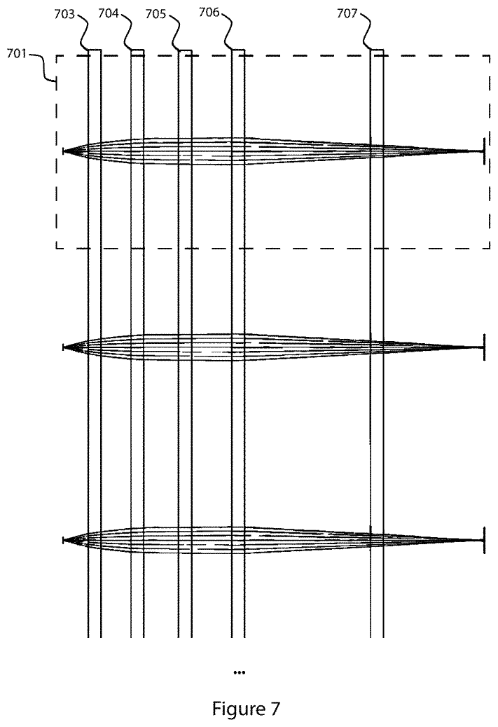

In one embodiment of the invention, the bi-telecentric projection system may be replicated. One example of said embodiment is illustrated in FIG. 7, wherein the elements with small sag illustrated in FIG. 6 (701) are replicated. In said embodiment, the four lenses of the bi-telecentric imaging system (603, 604, 606, 607) may be replicated on larger substrates (703, 704, 706, 707). In said embodiment, the diffractive element (605) may be replicated on a larger substrate (705). Said replication of the structure allows us to construct a large number of bi-telecentric projection systems as an array of structures.

This is useful because it allows us to assemble and align many structures in a single process. As the alignment process may be incredibly sensitive and time consuming, said process may substantially reduce the cost of bi-telecentric projection system. In one extension of said embodiment, said array of structures may be separated into smaller structures. Such separation may be done using a dicing saw. One variation of this extension may produce one bi-telecentric projection system on each smaller structure. In another variation of this extension, each smaller structure may produce two or more bi-telecentric projection systems.

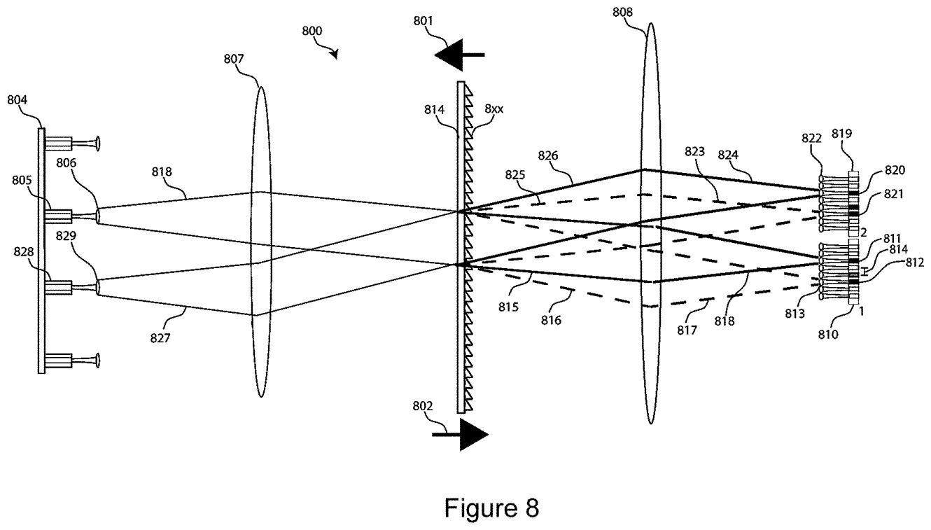

In one embodiment of the invention, a bi-telecentric WDM projection device may operate as a multiplexing system or a de-multiplexing system. One example of said embodiment is shown in FIG. 8, wherein a bi-telecentric multiplexing system (800) shows light progressing in a direction (802) away from an array (804) of fiber cores, thereby operating as a de-multiplexing system. FIG. 8 also shows light progressing in a direction (801) toward the array (804) of fiber cores, thereby operating as a multiplexing system. In an extension of said example, the light may propagate in both directions (801 and 802) simultaneously.

In system 800, light from an optical fiber array (804) may be emitted from an optical fiber (805) and through a collimating lens (806) such that the resulting light is imaged through a bi-telecentric imaging system consisting of two lens groups (807 and 808) to substantially form an image onto a detector array (810) wherein each detector (811 and 812) may have light focused further through a lenslet (813). In system 800, a diffractive optic (814) may be inserted into the bi-telecentric system such that wavelengths are deflected along substantially different angles (815 and 816) such that the second lens group (808) focuses different wavelengths onto substantially different focused beams (817 and 818).

Said focused beams fall onto detectors (811 and 812) at substantially different positions corresponding to their wavelength and the position of the image of the optical fiber. Thus, the bi-telecentric WDM projection system 800 performs wavelength de-multiplexing from an optical fiber array 804 onto an array of photodetectors 810. In FIG. 8, the light is emitted by an array of VCSELs (819), wherein each VCSEL (820 or 821) emits light with a wavelength corresponding to its position within the array of VCSELs and the position of the image of the target optical fiber (828).

Said light is collimated by a lenslet (822) such that the bi-telecentric WDM projection device with two lens groups (808 and 807) as well as a diffractive optic (814) combine the many separate emitted beams (823 and 824) which are collimated by the second lens group (808) to impinge on the diffractive at different angles (825 and 826) into a single beam (827) which focuses onto a single optical fiber core (828) within a larger optical fiber array (804) through a single lenslet (829). Thus the bi-telecentric WDM projection system (800) performs wavelength multiplexing from an array of VCSELs (819) to an optical fiber array (804).

In one variation of the embodiment of FIG. 8, a WDM system in which the light emitted by fiber 805 is de-multiplexed whereas the light emitted by fiber 828 is multiplexed. In other variations of the embodiment, light may be multiplexed and de-multiplexed from a single fiber. If the detector at position 811 is replaced with a VCSEL, then the light emitted by fiber 805 is de-multiplexed onto detector 812, and the light emitted by VCSEL 811 is multiplexed into fiber 805. A similar result may be performed for Fiber 828 by replacing VCSEL 821 with a detector. Thus the system may achieve multiplexing and de-multiplexing for individual fibers. In extensions of this variation, one may completely interleave VCSELs and detectors into an array of VCSELs and detectors. Said extension may see VCSELs alternating with detectors at each position.

Variations of said embodiment may be constructed using variations on the underlying technologies, design methods, and fabrication methods.
In one variation, the diffractive element may be constructed as a thick hologram with Bragg selectivity adding isolation between channels.
In one variation, the diffractive element may be constructed as a diffractive optical element with multiple phase levels at each location; in said diffractive optical element, the optical phase has been optimized to couple said angles and sufficiently suppress other angles.
In one variation, the diffractive element may be constructed as a binary phase modulation structure.
In one variation, the diffractive element may be a blazed grating. In one variation, the phase structures of the diffractive element may be individually produced substantially with a ramp such that the diffraction from each phase structure interacts in a manner similar to a blazed grating.
In some variations of the embodiment, the distortion of the imaging system is calculated from the design; in other variations, the distortion of the imaging system is measured. In extensions of said variation the measured distortion is used to create a single diffractive element design for all subsequent parts; in other extensions, the measurement is used to create a unique diffractive element design for each system produced.
In some variations of the embodiment, the gratings of the diffractive optic are created solely from the pre-calculated input and output angles. In other variations, the input and output angles are used to create a superposition of summed gratings, and this superposition of summed gratings is used as a starting condition for an optimizer based on the Gerchberg-Saxton algorithm, wherein said optimizer searches for the maximum diffraction efficiency and the minimum cross-talk. In more extensive variations, input and output angles are not used; instead, the input and output wavefront are used, and an optimizer is built to maximize coupling between wavefronts while minimizing cross-talk.

Additional variations of these inventions would apply to differing optical fiber technologies, detector technologies, laser technologies, lens technologies, grating technologies, as well as the methods for to assembling, aligning, and verifying the systems.
In variations on these inventions, single core optical fibers may be placed to ensure precise positioning of the fiber cores in the row; or one or more waveguides may be assembled into a semiconductor substrate; or one or more multi-core optical fibers may be placed into the system such that the fiber cores fall substantially along a row.
Variations of these inventions may use detectors constructed of materials including but not limited to GaAs, Si, metal oxides, or InGaAs. Detectors may be positioned onto a surface as one or more sets using one or more fabrication methods such as a wide area lithography process, or they may be individually positioned.
Variations of these inventions may use lasers including edge emitters, VCSELs, fiber lasers, or gas lasers. Sets of said lasers may be constructed using lithography processes, or they may be individually positioned. Sets of said lasers may be aligned to kinematic features or placed in fiber bundles before being installed into the system.
Variations of these inventions may use lens technologies including refractive lenses, Fresnel lenses, and meta lenses. In some embodiments, one or more lenses may be replaced by a set of lenses which produce substantially the same result. In other embodiments, one or more lenses may be consolidated into a single lens system which produces substantially the same result.
Variations of these inventions may use grating technologies constructed of materials including but not limited to glass, photopolymers, semiconductors, or metals. In some embodiments, the gratings may be etched into a surface, they may be holographic gratings, or they may be deposited onto a surface. Said gratings may comprise grating rulings and may appear substantially linear in nature. In some embodiments, it is advantageous for the grating to include curvature in a manner similar to a Fresnel lens. In some embodiments, the grating may be substantially pseudorandom in nature.

What is claimed is:

1. A wavelength division multiplexing system comprising:
a source array for providing input beams;
a first lens group and a second lens group configured to create an imaging configuration;
the first lens group comprising two positive focal length lenses configured to collimate input beams;
the second lens group comprising a negative focal length lens configured to bring the collimated beams to a weak focus, and a positive focal length lens configured to reduce field curvature;
an output array of locations disposed on an opposite side of the imaging configuration from the source array; and
a diffractive element oriented between the first lens group and the second lens group at a Fourier plane of the imaging configuration, the diffractive element configured to enable specific input beams to map to selected output array locations based on the wavelengths of the input beams.

2. The system of claim 1 configured for operation in a reverse direction such that beams from the output array of locations are mapped to specific locations in the source array.

3. The system of claim 1 wherein the diffractive element is either a blazed grating, a hologram, or a binary phase modulator.

4. The system of claim 1 wherein the source array comprises VCSELs.

5. The system of claim 1 wherein the output array comprises an array of optical fibers.

6. The system of claim 1 wherein the lenses are Fresnel lenses and a total track length of the system is less than 10 mm.

7. The system of claim 1 wherein one or more of the lenses is a meta lens.

8. The system of claim 1 wherein the imaging configuration consists essentially of two lenses in the first lens group and two lenses in the second lens group.

9. The system of claim 8 configured to have a track length of under 10 mm.

10. The system of claim 1 configured to have an absolute value of magnification between 1.5 and 6.

11. A wavelength division multiplexing system comprising:
two lens elements disposed in an imaging configuration;
a diffractive element disposed between the two lens elements;
an array of light sources; and
an array of receivers;
wherein individual beams from the array of light sources are directed to specific receivers by the two lens elements and the diffractive element based on beam wavelengths; and
wherein the diffractive element is configured to compensate for distortion caused by the two lens elements.

12. The system of claim 11 wherein the receivers comprise detectors.

13. The system of claim 11 wherein the receivers comprise optical fibers.

14. The system of claim 11 wherein the light sources comprise an array of optical fibers.

15. The system of claim 11 wherein the light sources comprise VCSELs.

16. The system of claim 11 configured to also operate in a reverse direction by including transmitters in the receiver array and providing receiving optical fibers at the source array.

17. The system of claim 11 configured to have an absolute value of magnification between 1.5 and 6.

18. The system of claim 11 having 8 receivers.

19. The method of accomplishing WDM comprising the steps of:
in a bi-telecentric lens system having a first lens set and a second lens set, disposing a diffractive element between the first lens set and the second lens set;
configuring the lens system and the diffractive element to accomplish WDM of beams from an array of light sources to an array of image locations; and
compensating for distortion caused by the lens system.

20. The method of claim 19 wherein the compensating step includes the steps of measuring distortion caused by the lens system and configuring the diffractive element based on the measured distortion.

21. The method of claim 20 wherein the compensating step further includes the step of adjusting spacing of lenses in the lens sets based on measured distortion.

22. The method of claim 19 wherein the compensating step includes the steps of calculating distortion caused by the lens system and configuring the diffractive element based on the calculated distortion.

23. The method of claim 22 further comprising the step of also measuring distortion caused by the lens system and configuring the diffractive element based on the measured distortion.

24. The method of claim 19, further comprising the step of:
fabricating multiple sets of each lens element within the first lens set and second lens set on a single substrate for each lens element and fabricating multiple sets of the diffractive element on a single substrate.

25. The method of claim 24, further comprising the steps of adjusting orientation of each substrate.

26. The method of claim 25, further comprising the step of separating each set of lens systems and its corresponding diffractive element with a dicing saw.

27. The method of claim 19 further comprising the step of orienting detectors at image locations based on distortion caused by the lens system.

28. The method of claim 19, further comprising the step of interleaving VCSELs with detectors.
